(19) United States
(12) Patent Application Publication
(10) Pub. No.: US 2007/0272437 A1
(43) Pub. Date: Nov. 29, 2007

(54) Printed circuit board and semiconductor package using the same

(75) Inventor: Takeshi Kondo, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 11/802,758

(22) Filed: May 24, 2007

(30) Foreign Application Priority Data
May 25, 2006 (JP) 2006-145245

(51) Int. Cl. H05K 1/16

(52) U.S. Cl. 174/260

(57) ABSTRACT

In a printed board having a wiring pattern and an NSMD type land, the present invention prevents disconnection between the land and the wiring pattern and separation of the land from the printed board. The printed circuit board has a main wiring pattern, a protective film covering the main wiring pattern and having an opening formed therein, and a land located inside of the opening of the protective film so that the land is spaced from a circumferential edge of the opening of the protective film. The printed circuit board also has an auxiliary wiring pattern including a first auxiliary wiring portion located under the protective film so as to surround the land and second auxiliary wiring portions radially extending from the land to the first auxiliary wiring portion.

This application claims priority to prior application of JP 2006-145245, the disclosure of which is incorporated herein by reference.

### BACKGROUND OF THE INVENTION

1. Field of the Invention

The present invention relates to a printed circuit board, and more particularly to a printed circuit board on which a BGA type semiconductor package is mounted and a BGA type semiconductor package using such a printed circuit board.

2. Description of the Related Art

A printed board used in a BGA package has a large number of lands for fusing and fixing solder balls of the BGA package. Furthermore, a printed board onto which a BGA package is mounted has a large number of lands for fusing and fixing solder balls of the BGA package.

Solder mask defined (SMD) type lands and non-solder mask defined (NSMD) type lands have been known as lands used in printed boards. In an SMD type land, the effective shape of the land is defined by an opening in a protective film formed on printed board wiring. In an NSMD type land, the effective shape and size of the land are not defined by an opening in a protective film but by the land formed inside of the opening. The present invention relates to a printed board having NSMD type lands.

FIGS. 1A and 1B show a structure of a conventional NSMD type land. FIGS. 1A and 1B illustrate a region including one of lands in a printed board. As shown in FIGS. 1A and 1B, a signal line 8 and a circular land 1 connected to the signal line 8 are formed on a surface 7-1 of a printed board 7. Furthermore, a solder resist film 6 for preventing attachment of solder and protecting the surface 7-1 of the printed board 7 is formed on the surface 7-1 of the printed board 7 except the land area. Thus, the solder resist film 6 has an opening 9 in which the land 1 is located in such a state that the insulator surface 7-1 of the printed board 7 is exposed between a circumferential edge of the opening 9 and an outer edge of the land 1. The signal line 8 that is located under the solder resist film 6 extends from the circumferential edge of the opening 9 to the land 1 so that the signal line 8 is integrally connected to the land 1.

The printed circuit board has a large number of the above land structures, and a BGA type package is mounted onto the printed circuit board. At that point, when stress is applied to the printed circuit board, a warp may be produced in the printed board 7. Such a warp is caused by stress applied due to a temperature cycling test or other factors. If the land cannot stand an excessive warp, troubles occur in the lands.

FIGS. 2A and 2B show that stress is applied to a printed board on which a BGA type package is mounted and that the printed board is warped. FIG. 2A illustrates a printed board 7 on which a BGA type package 30 is mounted with a warp of the printed board 7. FIG. 2B is an enlarged cross-sectional view of one of land areas 35. FIG. 2B shows a breakage (disconnection) 5 of a signal line 8, which is formed integrally with a land 1, at a circumferential edge of an opening formed in a solder resist film 6 and a separation 4 of the land 1 from the printed board 7. The breakage 5 of the signal line 8 and the separation 4 of the land 1 are caused by the warp of the printed board 7.

These deficiencies produce defects in electric connection via solder balls 32, thereby deteriorating the reliability of the printed board 7.

Japanese laid-open patent publication No. 11-354680 (Patent Document 1) discloses a structure in which solder balls are fixed to NSMD type lands provided in a printed board with a BGA package. This document teaches that a shear strength is reduced to a larger extent by a temperature cycling test as compared to a case where solder balls are fixed to SMD type lands. In order to resolve this drawback, Patent Document 1 has proposed the following land structure. In an NSMD type land, reinforcement patterns are formed on a surface of a printed board so as to radially extend from a circular land to portions located below a protective film pattern. By thus forming the reinforcement patterns under the protective film, it is possible to fix the land firmly to the printed board and suppress the movement in a shear direction.

The land structure having the reinforcement patterns disclosed in Patent Document 1 is expected to increase the strength. However, this land structure impairs electric connection when the signal line pattern connected to the land is broken at a circumferential edge of an opening in the protective film pattern.

Japanese laid-open patent publication No. 2005-51240 (Patent Document 2) teaches that a solder ball may come off an SMD type land during a reliability test. This document also teaches occurrence of disconnection in a pattern connecting portion connected to an NSMD type land and separation of an NSMD type land from a printed board. In order to resolve these drawbacks, Patent Document 2 has proposed a structure in which an SMD type and an NSMD type are combined within one land.

### SUMMARY OF THE INVENTION

It is an object of the present invention to provide a printed circuit board having a land structure capable of enhancing a shear strength of a land and improving electric connection between the land and a signal line, and to provide a semiconductor package using such a printed circuit board.

According to a first aspect of the present invention, there is provided a printed circuit board having a main wiring pattern, a protective film covering the main wiring pattern and having an opening formed therein, and a land located inside of the opening of the protective film so that the land is spaced from a circumferential edge of the opening of the protective film. The printed circuit board has an auxiliary wiring pattern including a first auxiliary wiring portion located under the protective film so as to surround the land and second auxiliary wiring portions radially extending from the land to the first auxiliary wiring portion.

It is desirable that the main wiring pattern should be connected to a peripheral edge of the first auxiliary wiring portion.

Each of the second auxiliary wiring portions may have a first end connected to the land and a second end located under the protective film.

The land may be connected to the main wiring pattern via the second auxiliary wiring portions.

In one embodiment of the present invention, the first auxiliary wiring portion has an annular shape.

The first auxiliary wiring portion may have a rhombic shape, and the second auxiliary wiring portions may extend to corners of the rhombic shape of the first auxiliary wiring portion.

Alternatively, the first auxiliary wiring portion may have a rectangular shape, and the second auxiliary wiring portions may extend to sides of the rectangular shape of the first auxiliary wiring portion.

According to a second aspect of the present invention, there is provided a printed circuit board on which a BGA type IC package is mounted. The printed circuit board has a land and an auxiliary wiring pattern including a first auxiliary wiring portion located under a protective film so as to surround the land and second auxiliary wiring portions radially extending from the land to the first auxiliary wiring portion. The BGA type IC package is fixed to the land by a solder ball.

According to a third aspect of the present invention, there is provided a semiconductor package having a printed circuit board and a semiconductor chip mounted on the printed circuit board. The printed circuit board includes a land provided on a surface of the printed circuit board opposite to the semiconductor chip and an auxiliary wiring pattern including a first auxiliary wiring portion located under a protective film so as to surround the land and second auxiliary wiring portions radially extending from the land to the first auxiliary wiring portion.

According to the present invention, a signal line is not connected directly to a land inside of a circumferential edge of an opening but is connected to the land via a first auxiliary wiring portion and second auxiliary wiring portions. Therefore, there is little likelihood that the signal line is broken. Since the second auxiliary wiring portions pass across the circumferential edge of the opening, they may be broken near the circumferential edge of the opening when mechanical stress such as thermal stress is applied to the second auxiliary wiring portions. However, because a plurality of second auxiliary wiring portions are provided, even if one of the second auxiliary wiring portions is broken, the other second auxiliary wiring portions are still connected to the signal line via the first auxiliary wiring portion, thereby maintaining electric connection. Furthermore, the circular land is formed integrally with a plurality of second auxiliary wiring portions. Some parts of the second auxiliary wiring portions are fixed by a protective film. Accordingly, the land is prevented from being separated from the printed board when thermal stress is applied to the land.

The above and other objects, features, and advantages of the present invention will be apparent from the following description when taken in conjunction with the accompanying drawings which illustrate preferred embodiments of the present invention by way of example.

### BRIEF DESCRIPTION OF THE DRAWINGS

FIG. 1A is a plan view showing a conventional pattern of a land and a signal line;

FIG. 1B is a cross-sectional view of FIG. 1A;

FIG. 2A is a cross-sectional view schematically showing a deformed printed board using a conventional pattern of a land and a signal line;

FIG. 2B is an enlarged cross-sectional view showing one of land areas in the printed board shown in FIG. 2A;

FIG. 3A is a plan view showing a region around one of lands in a printed circuit board according to a first embodiment of the present invention;

FIG. 3B is a cross-sectional view taken along line A-A of FIG. 3A;

FIG. 3C is a cross-sectional view taken along line B-B of FIG. 3A;

FIG. 4A is a plan view showing shapes of the land and an auxiliary wiring pattern in the first embodiment of the present invention;

FIG. 4B is a plan view showing shapes of a land and an auxiliary wiring pattern in a variation of the first embodiment of the present invention;

FIG. 5A is a plan view showing shapes of a land and an auxiliary wiring pattern in another variation of the first embodiment of the present invention; and

FIG. 5B is a plan view showing shapes of a land and an auxiliary wiring pattern in still another variation of the first embodiment of the present invention.

FIG. 6 is a cross sectional view schematically showing a semiconductor package to which the land structure of FIG. 3A is applied.

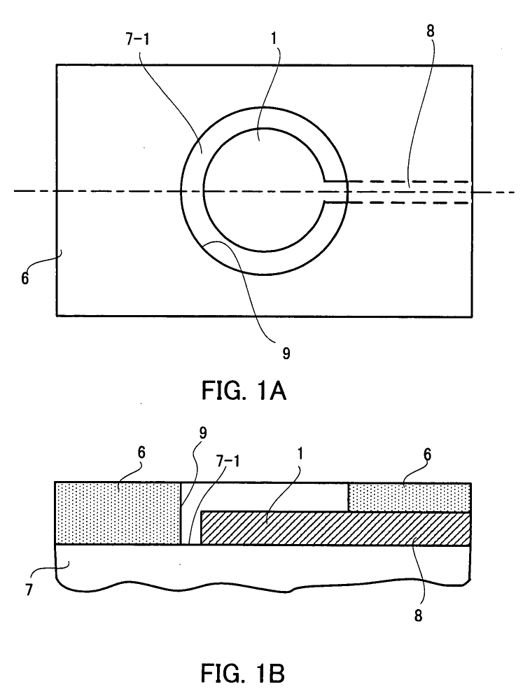

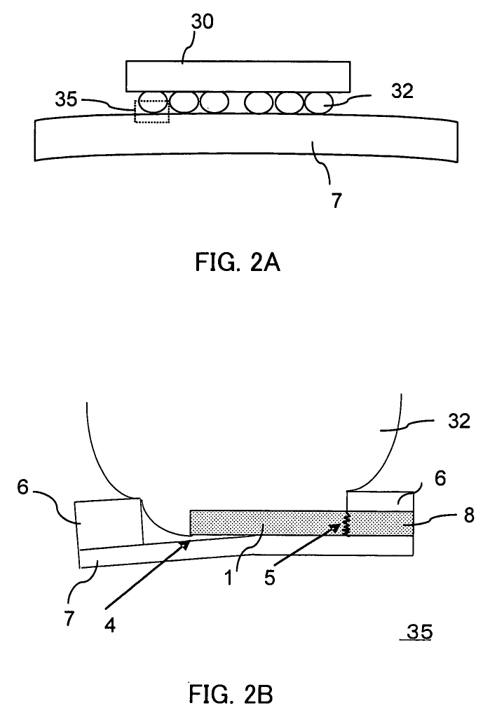

### DETAILED DESCRIPTION OF THE PREFERRED EMBODIMENTS

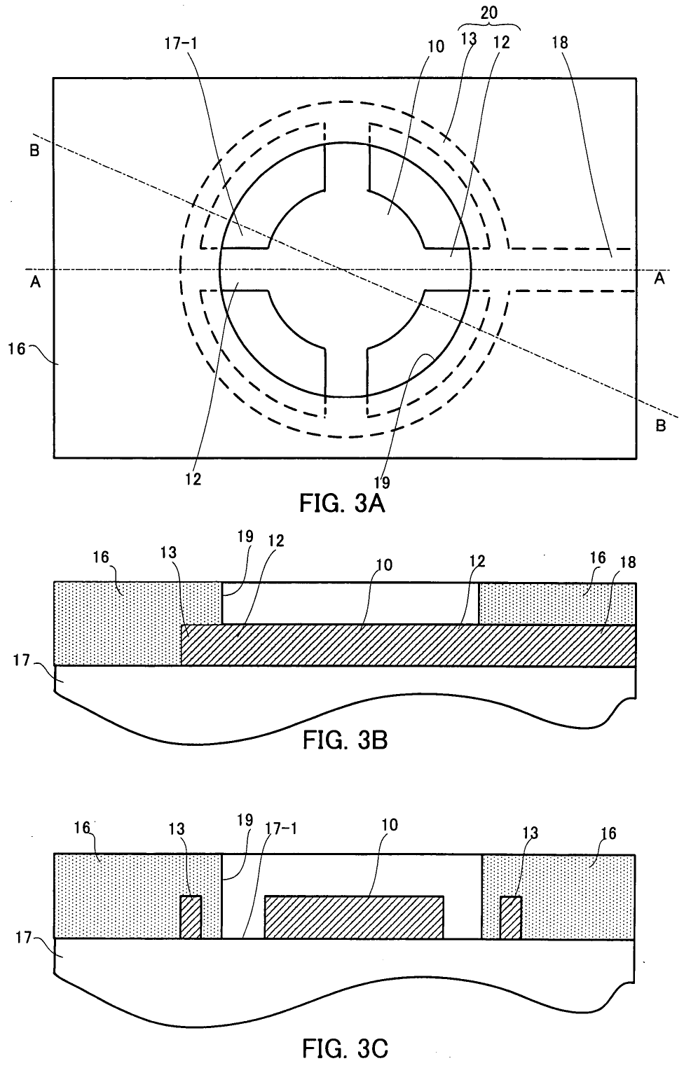

Embodiments of the present invention will be described below with reference to FIGS. 3A to 5B.

FIGS. 3A to 3C are enlarged views showing one of land areas in a printed circuit board according to a first embodiment of the present invention.

FIG. 3A is a plan view, FIG. 3B is a cross-sectional view taken along line A-A of FIG. 3A, and FIG. 3C is a cross-sectional view taken along line B-B of FIG. 3A.

As shown in FIGS. 3A to 3C, a circular land 10, a signal line 18 as part of a main wiring pattern, and an auxiliary wiring pattern 20 are formed on a surface 17-1 of an insulator printed board 17. The auxiliary wiring pattern 20 includes a first auxiliary wiring portion 13 having an annular shape and a plurality of second auxiliary wiring portions 12 each having a linear shape. The second auxiliary wiring portions 12 connect the land 10 to the first auxiliary wiring pattern 13. Specifically, the second auxiliary wiring portions 12 radially extend from the land 10 to the annular auxiliary wiring portion 13. The signal line 18 is connected to an outer edge of the first auxiliary wiring portion 13. The land 10, the first auxiliary wiring portion 13, and the second auxiliary wiring portions 12 are made of copper and formed in the same process.

A solder resist film 16 is formed as a protective film on the surface 17-1 of the printed board 17 on which the land 10, the first auxiliary wiring portion 13, and the second auxiliary wiring portions 12 have been formed. The solder resist film 16 serves to prevent solder from being attached to portions that require no wiring patterns. The solder resist film 16 is made of a transparent insulation material. After the solder resist film 16 is formed on the entire surface of the printed board 17, an opening 19 is formed in the land area of the solder resist film 16. The opening 19 has a circular shape located concentrically with the circular land 10 and the annular auxiliary wiring portion 13. The opening 19 has a circumferential edge located between an outer edge of the circular land 10 and an inner edge of the annular auxiliary wiring portion 13. Thus, the entire annular auxiliary wiring portion 13 is located under the solder resist film 16. Some portions of the second auxiliary wiring portions 12 are located under the solder resist film 16. The second auxiliary wiring portions 12 are connected to the land 10 at portions located inside of the opening 19, which are not covered with the solder resist film 16.

In the above example, the opening 19 is formed after the solder resist film 16 has been formed on the entire surface of the printed board 17. However, the solder resist film 16 may be formed on a region except the area of the opening 19 from the beginning.

Unlike the prior art, there is little likelihood that the signal line 18 is broken in the present embodiment. This is because the signal line 18 is not connected directly to the land 10 inside of the circumferential edge of the opening 19 but is connected to the land 10 via the first auxiliary wiring portion 13 and the second auxiliary wiring portions 12. Since the second auxiliary wiring portions 12 pass across the circumferential edge of the opening 19, they may be broken near the circumferential edge of the opening 19 when mechanical stress such as thermal stress is applied to the second auxiliary wiring portions 12. However, because four auxiliary wiring portions 12 are provided, even if one of the second auxiliary wiring portions 12 is broken, the other second auxiliary wiring portions 12 are still connected to the signal line 18 via the first auxiliary wiring portion 13, thereby maintaining electric connection. Furthermore, the circular land 10 is formed integrally with a plurality of second auxiliary wiring portions 12, which are fixed by the solder resist film 16. Accordingly, the land 10 is prevented from being separated from the printed board 7 when thermal stress is applied to the land 10.

In the first embodiment, the land 10 has a circular shape, and the auxiliary wiring pattern includes the first auxiliary wiring portion 13 having an annular shape and the second auxiliary wiring portions 12 interconnecting the land 10 and the first auxiliary wiring portion 13. However, the auxiliary wiring pattern can be modified in various different ways.

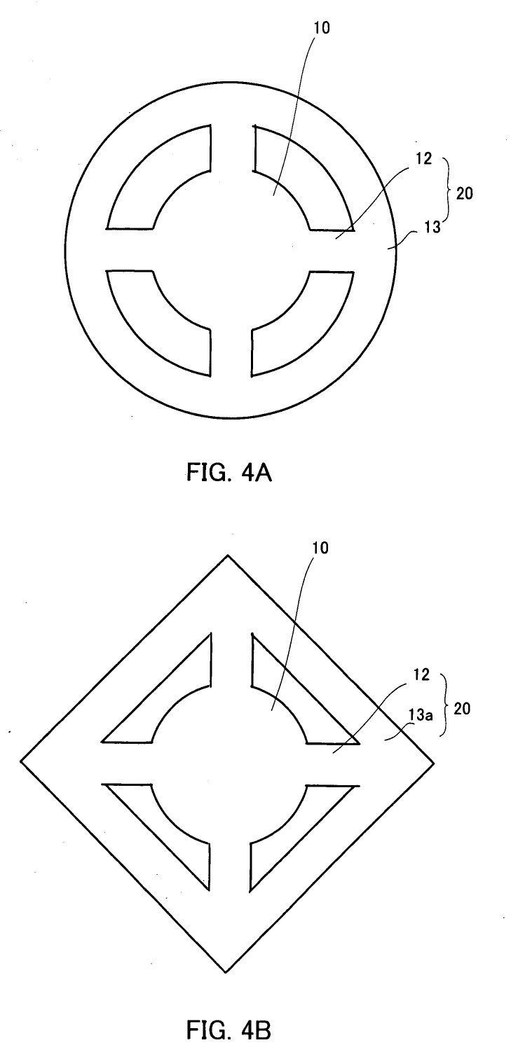

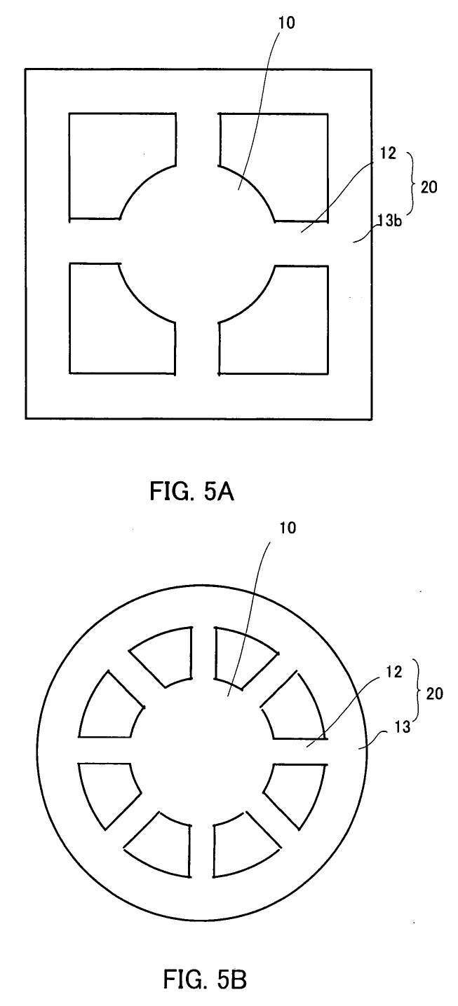

Some variations of the land and the auxiliary wiring pattern will be described below with reference to FIGS. 4A to 5B.

FIG. 4A is a plan view showing shapes of the land 10 and the auxiliary wiring pattern 20 in the aforementioned first embodiment. As shown in FIG. 4A, the land 10 has a circular shape, and the auxiliary wiring pattern 20 includes the first auxiliary wiring portion 13 having an annular shape and the second auxiliary wiring portions 12 radially extending from the land 10 to the first auxiliary wiring portion 13.

FIG. 4B shows a variation of the first embodiment, which includes a first auxiliary wiring portion 13a having a rhombic shape. Other portions are the same as those in FIG. 4A.

FIG. 5A shows another variation of the first embodiment, which includes a first auxiliary wiring portion 13b having a square or rectangular shape. Other portions are the same as those in FIG. 4A.

FIG. 5B shows still another variation of the first embodiment. This variation includes the same first auxiliary wiring portion 13 as that in FIG. 4A but differs from FIG. 4A in provision of eight second auxiliary wiring portions 12. As the number of the second auxiliary wiring portions 12 is larger, a land can be prevented more effectively from being separated from a printed board due to mechanical stress such as thermal stress. However, if an excessive number of second auxiliary wiring portions 12 are provided, then the features of the NSMD type structure are lost.

The land structure in a printed circuit board has been described in the above embodiment and its variations. In this case, if a BGA package is mounted onto a printed circuit board including a large number of lands having the above structure so that solder balls are fused onto the lands, then it is possible to improve electric problems or strength problems that would be caused by lands in a conventional printed circuit board on which a BGA package is mounted.

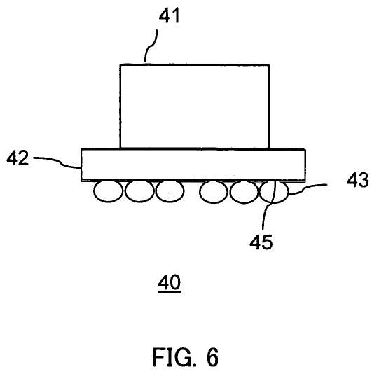

Furthermore, the land structure shown in the above embodiment and its variations is applicable to a BGA type semiconductor package and the like. Specifically, as shown in FIG. 6, a chip 41 is mounted on a surface of a substrate 42 on which a semiconductor chip is to be mounted, and the aforementioned land structure, for example, one shown in FIGS. 3A to 3C, is applied to an opposite surface of the substrate 42. Then, solder balls 43 are fused onto the land structure to produce a semiconductor package 40. In this case, thermal and mechanical strength is improved for the semiconductor package having the NSMD type land structure.

Although certain preferred embodiments of the present invention have been shown and described in detail, the present invention is not limited to those illustrated embodiments. It should be understood that various changes and modifications may be made therein without departing from the scope of the appended claims.

What is claimed is:

1. A printed circuit board comprising:
a main wiring pattern;
a protective film covering said main wiring pattern and having an opening formed therein;
a land located inside of said opening of said protective film so that said land is spaced from a circumferential edge of said opening of said protective film; and
an auxiliary wiring pattern including:
i) a first auxiliary wiring portion located under said protective film so as to surround said land, and
ii) second auxiliary wiring portions radially extending from said land to said first auxiliary wiring portion.

2. The printed circuit board as recited in claim 1, wherein said main wiring pattern is connected to a peripheral edge of said first auxiliary wiring portion.

3. The printed circuit board as recited in claim 2, wherein each of said second auxiliary wiring portions has a first end connected to said land and a second end located under said protective film.

4. The printed circuit board as recited in claim 3, wherein said land is connected to said main wiring pattern via said second auxiliary wiring portions.

5. The printed circuit board as recited in claim 4, wherein said first auxiliary wiring portion has an annular shape.

6. The printed circuit board as recited in claim 4, wherein said first auxiliary wiring portion has a rhombic shape,
wherein said second auxiliary wiring portions extend to corners of said rhombic shape of said first auxiliary wiring portion.

7. The printed circuit board as recited in claim 4, wherein said first auxiliary wiring portion has a rectangular shape,
wherein said second auxiliary wiring portions extend to sides of said rectangular shape of said first auxiliary wiring portion.

8. The printed circuit board as recited in claim 1, wherein a BGA type package is mounted on said printed circuit board by fixing a solder ball on said land.

9. A semiconductor package comprising:
a printed circuit board; and
a semiconductor chip mounted on said printed circuit board, said printed circuit board including:
i) a land provided on a surface of said printed circuit board opposite to said semiconductor chip, and
ii) an auxiliary wiring pattern including a first auxiliary wiring portion located under a protective film so as to surround said land and second auxiliary wiring portions radially extending from said land to said first auxiliary wiring portion.
